(19) United States
(12) Patent Application Publication
(10) Pub. No.: US 2022/0319466 A1
(43) Pub. Date: Oct. 6, 2022

(54) DISPLAY DEVICE AND PROXIMITY SIGNAL SENSING METHOD USING INPUT SENSOR

(71) Applicant: Samsung Display Co., Ltd., Yongin-Si (KR)

(72) Inventors: YONGJIN JEE, Suwon-si (KR); SOONGYU LEE, Seoul (KR); HOEUNG LEE, Suwon-si (KR)

(21) Appl. No.: 17/693,808

(22) Filed: Mar. 14, 2022

(30) Foreign Application Priority Data
Mar. 30, 2021 (KR) 10-2021-0041175

(51) Int. Cl. G09G 5/10; H04M 1/72454; G09G 3/32

(52) U.S. Cl. CPC G09G 5/10; H04M 1/72454; G09G 3/32; G09G 2320/0633; G09G 2320/064; G09G 2320/0653; G09G 2320/0686; G09G 2354/00

(57) ABSTRACT

Disclosed is a display device including a controller executing a proximity sensing mode in which a proximity signal is sensed in response to a start signal, a display reducing luminance of a display panel to target luminance when the proximity sensing mode is executed, and a sensor sensing the proximity signal after reducing the luminance of a display panel to the target luminance.

### CROSS-REFERENCE TO RELATED APPLICATIONS

This application claims priority under 35 U.S.C. § 119 to Korean Patent Application No. 10-2021-0041175 filed on Mar. 30, 2021, in the Korean Intellectual Property Office, the disclosures of which are incorporated by reference herein in their entireties.

### BACKGROUND

Embodiments of the present disclosure described herein relate to a display device and a proximity signal sensing method using an input sensor, and more particularly, relate to a display device having improved reliability, and a proximity signal sensing method using an input sensor.

A display device includes a smartphone or mobile phone that displays an image. Nowadays, the mobile phone has a function for turning off a screen when a user makes a call and for turning on the screen again when the call ends. That is, the mobile phone usually controls the screen by detecting the approach of a user's ear or face through an infrared sensor. An input sensor detects the user's touch. The input sensor is disposed on a display panel that displays images. The input sensor may sense not only a touch but also various input signals.

### SUMMARY

Embodiments of the present disclosure provide a display device that detects a proximity signal through an input sensor, and a proximity signal sensing method using the input sensor.

Embodiments of the present disclosure provide a display device that reduces noise caused by a display panel in a process of sensing a proximity signal through an input sensor and has improved detection performance, and a proximity signal sensing method using an input sensor.

According to an embodiment, a display device includes a controller executing a proximity sensing mode in which a proximity signal is sensed in response to a start signal, a display reducing luminance of a display panel to target luminance when the proximity sensing mode is executed, and a sensor sensing the proximity signal after reducing the luminance of a display panel to the target luminance.

The start signal may be a signal for starting a phone call by a user.

The display may include the display panel and a display driver integrated circuit electrically connected to the display panel. The display driver integrated circuit may reduce the luminance of the display panel to the target luminance.

The display may include a first frame and a second frame that follows the first frame. First luminance of the display panel in the first frame may be greater than second luminance of the display panel in the second frame.

A driving voltage applied from the display driver integrated circuit to the display panel in the second frame may be less than a driving voltage applied in the first frame.

A second driving time in the second frame may be less than a first driving time in the first frame.

A driving voltage of the second frame may be less than a driving voltage of the first frame. A driving time in the second frame may be less than a driving time in the first frame.

The target luminance may be an average of the first luminance and the second luminance.

The sensor may include an input sensor and a sensor driving circuit electrically connected to the input sensor. The sensor driving circuit may be synchronized with the display so as to detect the proximity signal through the input sensor.

The sensor may sense the proximity signal in the second frame.

When the proximity sensing mode is executed, the display may gradually reduce the luminance to the target luminance.

The display device may include a first area disposed adjacent to a speaker and a second area disposed adjacent to the first area.

The display may reduce the luminance of the display panel in the first area to the target luminance.

The sensor may sense the proximity signal in the first area.

The sensor may be disposed on the display so as to overlap the display in a plan view.

According to an embodiment, a proximity signal sensing method using an input sensor includes executing a proximity sensing mode in which the input sensor senses a proximity signal instead of a touch signal when the controller receives a start signal, reducing luminance of a display panel to target luminance when the proximity sensing mode is executed, and sensing the proximity signal by a sensor synchronized with the display.

The display panel may include a first frame and a second frame that follows the first frame. First luminance of the display panel in the first frame may be greater than second luminance of the display panel in the second frame.

The display may include a display driver integrated circuit. The display driver integrated circuit may set a driving voltage of the second frame so as to be lower than a driving voltage of the first frame.

The sensor may include a sensor driving circuit. The sensor driving circuit may detect the proximity signal in the second frame.

### BRIEF DESCRIPTION OF THE DRAWINGS

The above and other objects and features of the present disclosure will become apparent by describing in detail embodiments thereof with reference to the accompanying drawings.

FIG. 1 is a perspective view of a display device according to an embodiment of the present disclosure.

FIG. 2 is an exploded perspective view of a display device according to an embodiment of the present disclosure.

FIG. 3 is a block diagram of a display device, according to an embodiment of the present disclosure.

FIGS. 4A and 4B are cross-sectional views of a display module, according to an embodiment of the present disclosure.

FIG. 5 is an enlarged cross-sectional view of a display module, according to an embodiment of the present disclosure.

FIGS. 6A and 6B are block diagrams of a display device according to an embodiment of the present disclosure.

FIGS. 7A and 7B are flowcharts illustrating a proximity signal sensing method using an input sensor, according to an embodiment of the present disclosure.

FIG. 8 is a graph illustrating a decrease in luminance of a display panel, according to an embodiment of the present disclosure.

FIGS. 9A, 9B and 9C are graphs illustrating a method of lowering luminance of a display panel, according to an embodiment of the present disclosure.

FIG. 10 is a plan view of a display module according to an embodiment of the present disclosure.

### DETAILED DESCRIPTION

In this specification, when a component (or area, layer, portion, or the like) is described as being “on”, “connected to”, or “coupled to” another component, it means that the component may be directly positioned/connected/coupled on the other component or a third component may be interposed between them.

Like reference numerals refer to like components. Also, in drawings, the thickness, ratio, and dimension of components are exaggerated for effectiveness of description of technical contents. The term “and/or” includes one or more combinations of the associated listed items.

The terms “first”, “second”, etc. are used to describe various components, but the components are not limited by the terms. The terms are used only to differentiate one component from another component. For example, a first component may be named as a second component, and vice versa, without departing from the spirit or scope of the present disclosure. A singular form, unless otherwise stated, includes a plural form.

Also, the terms “under”, “beneath”, “on”, “above”, etc. are used to describe a relationship between components illustrated in a drawing. The terms are relative and are described with reference to a direction indicated in the drawing.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Unless otherwise defined, all terms (including technical terms and scientific terms) used in this specification have the same meaning as commonly understood by those skilled in the art to which the present disclosure belongs. Furthermore, terms such as terms defined in commonly used dictionaries should be interpreted as having a meaning consistent with the meaning in the context of the related technology, and is explicitly defined herein unless interpreted in ideal or overly formal meanings.

Hereinafter, embodiments of the present disclosure will be described with reference to accompanying drawings.

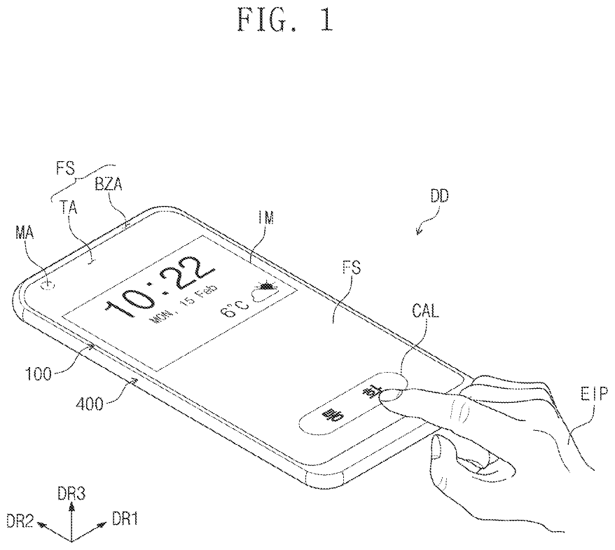

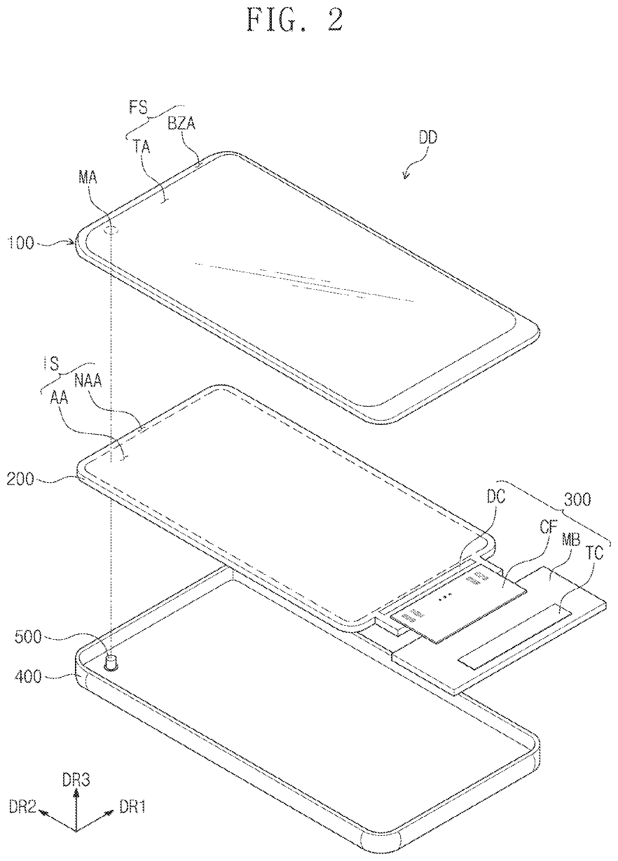

FIG. 1 is a perspective view of a display device according to an embodiment of the present disclosure. FIG. 2 is an exploded perspective view of a display device according to an embodiment of the present disclosure.

Referring to FIGS. 1 and 2, a display device DD may be a device activated depending on an electrical signal. The display device DD may include various embodiments. For example, in addition to large-sized display devices such as televisions, monitors, or external billboards, the display device DD may be used in small and medium-sized display devices such as a personal computer, a notebook computer, a personal digital terminal, a car navigation unit, a game console, a portable electronic device, and a camera. Furthermore, these are just presented as only an embodiment. It is obvious that these are capable of being employed in other display devices as long as these do not depart from the concept of the present disclosure. In an embodiment, the display device DD is illustrated as a smartphone.

The display device DD may display an image IM in a third direction DR3 on a display surface FS which is parallel to each of a first direction DR1 and a second direction DR2. The display surface FS on which the image IM is displayed may correspond to a front surface of the display device DD and may correspond to a front surface of a window 100. Hereinafter, the display surface of the display device DD, the front surface of the display device DD, and the front surface of the window 100 may use the same reference numerals. The image IM may include not only static images but also moving images. In FIG. 1, a clock window and application icons are illustrated as an example of the image IM.

In an embodiment, a front surface (or a top surface) and a back surface (or a bottom surface) of each element are defined with respect to a direction in which the image IM is displayed. The front surface may oppose the back surface in the third direction DR3, and the normal direction of each of the front surface and the back surface may be parallel to the third direction DR3. The third direction DR3 may be a direction intersecting the first direction DR1 and the second direction DR2. The first direction DR1, the second direction DR2, and the third direction DR3 may be perpendicular to one another.

In the present specification, a surface defined by the first direction DR1 and the second direction DR2 may be defined as a plane. “Being viewed from above a plane” may be defined as being viewed in the third direction DR3.

The display device DD may include the window 100, a display module 200, a driving circuit 300, a housing 400, and an electronic module 500. In an embodiment, an appearance of the display device DD may be implemented by coupling the window 100 and the housing 400.

The window 100 may include an optically transparent insulating material. For example, the window 100 may include glass or plastic. The window 100 may have a single-layer structure or a multi-layer structure. For example, the window 100 may include a plurality of plastic films bonded through an adhesive or may include a glass substrate and a plastic film that are bonded through an adhesive.

In a plan view, the window 100 may include a transparent area TA and a bezel area BZA. The transparent area TA may be an optically transparent area. Light transmittance of the bezel area BZA may be relatively low in comparison to the transparent area TA. The bezel area BZA may define a shape of the transparent area TA. The bezel area BZA is disposed adjacent to the transparent area TA and surrounds the transparent area TA.

The bezel area BZA may have a given color. The bezel area BZA may cover a peripheral area NAA of the display module 200 to prevent the peripheral area NAA from being visible from the outside. However, the present disclosure is not limited thereto. For example, the window 100 according to an embodiment of the present disclosure may not include the bezel area BZA.

In an embodiment of the present disclosure, a module area MA may overlap the electronic module 500. The display device DD may receive an external signal required for the electronic module 500 through the module area MA or may provide a signal output from the electronic module 500 to the outside. According to an embodiment of the present disclosure, the module area MA may be overlap the transparent area TA. Accordingly, a separate area in which the module area MA is disposed may not be required. Accordingly, a size of the bezel area BZA may be reduced.

The display module 200 may be disposed under the window 100. The display module 200 may display the image IM. The display module 200 may include a front surface IS including an active area AA and a peripheral area NAA. The active area AA may be activated depending on an electrical signal. The active area AA may be defined as a first area; and, the peripheral area NAA may be defined as a second area.

In an embodiment, the image IM may be displayed in the active area AA. The transparent area TA may overlap the active area AA. For example, the transparent area TA may overlay the active area AA or may overlap at least part of the active area AA. A user may visually perceive the image IM through the transparent area TA.

The peripheral area NAA may be an area covered by a bezel area BZA. The peripheral area NAA may be disposed adjacent to the active area AA. The peripheral area NAA may surround the active area AA. A driving circuit or driving wiring for driving the active area AA may be arranged in the peripheral area NAA.

In an embodiment, the display module 200 is assembled so that the active area AA and the peripheral area NAA having a flat surface face the transparent area TA and bezel area BZA in the window 100, respectively. However, the present disclosure is not limited thereto, and a part of the peripheral area NAA may be bent. At this time, a part of the peripheral area NAA faces a bottom surface of the display device DD, and thus the size of the bezel area BZA on the front surface of the display device DD may be reduced. Alternatively, the display module 200 may be assembled in a state where a part of the active area AA is bent. Alternatively, in the display module 200 according to an embodiment of the present disclosure, the peripheral area NAA may be omitted.

The driving circuit 300 may be electrically connected to the display module 200. The driving circuit 300 may include a display driver integrated circuit DC, a main circuit board MB, a sensor driving circuit TC, and a flexible film CF.

The display driver integrated circuit DC may be disposed adjacent to the flexible film CF on the peripheral area NAA of the display module 200. The sensor driving circuit TC may be disposed on the main circuit board MB. However, the present disclosure is not limited thereto. For example, as in the sensor driving circuit TC, the display driver integrated circuit DC may be disposed on the main circuit board MB.

The flexible film CF may be electrically connected to the display module 200. The flexible film CF may be connected to the pads of the display module 200 disposed in the peripheral area NAA. The flexible film CF may provide an electrical signal to the display module 200 for driving the display module 200. The electrical signal may be generated by a controller disposed on the flexible film CF or the main circuit board MB. The main circuit board MB may include various driving circuits for driving the display module 200, a connector for power supply, and the like. In an embodiment, the main circuit board MB may include the sensor driving circuit TC.

In an embodiment of the present disclosure, one area of the display module 200 corresponding to the module area MA may have a relatively high transmittance as compared to the active area AA that does not overlap the module area MA. For example, at least part of elements of the display module 200 in the module area MA may be removed. Accordingly, the electronic module 500 may easily transmit and/or receive signals through the module area MA.

The electronic module 500 may be disposed under the display module 200. In detail, the electronic module 500 may be disposed under the display panel. The electronic module 500 may overlap the module area MA in a plan view. The electronic module 500 may receive an external input transmitted through the module area MA or may provide a signal from the electronic module 500 to the outside through the module area MA. The electronic module 500 may include a speaker module, a camera module, and related electronic parts. In an embodiment, the electronic module 500 may include a speaker module that outputs a voice of a person at the other end of the line during a call. While a user is on the phone, the electronic module 500 may be disposed adjacent to the user's ear.

The housing 400 may be coupled to the window 100. The housing 400 may provide an inner space while being coupled to the window 100. The display module 200, the driving circuit 300 and the electronic module 500 may be accommodated in the inner space.

The housing 400 may include a material having relatively-high rigidity. For example, the housing 400 may include glass, plastic, or metal or may include a plurality of frames and/or plates that are composed of a combination thereof. The housing 400 may stably protect the display device DD accommodated in the inner space from an external impact.

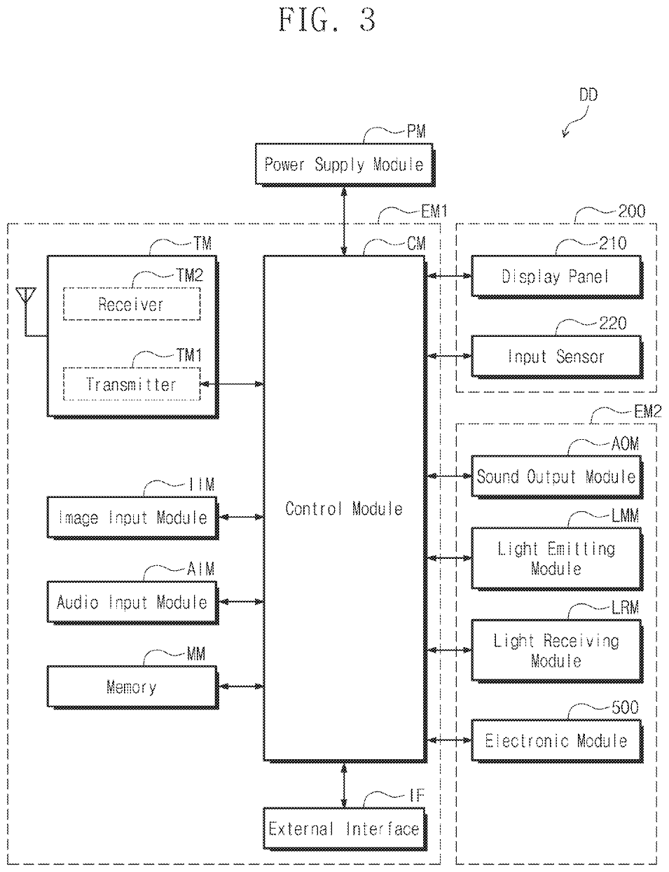

FIG. 3 is a block diagram of a display device, according to an embodiment of the present disclosure.

Referring to FIG. 3, the display device DD may include the display module 200, a power supply module PM, a first electronic module EM1, and a second electronic module EM2. The display module 200, the power supply module PM, the first electronic module EM1, and the second electronic module EM2 may be electrically connected to one another.

The display module 200 may include a display panel 210 and an input sensor 220.

The display panel 210 may generates the image IM. The image IM generated by the display panel 210 is displayed on the front surface IS, and is visually perceived by a user from the outside through the transparent area TA.

The input sensor 220 detects an external input EIP applied from the outside. For example, the input sensor 220 may detect an external input EIP provided to the window 100. The external input EIP may be a user input. The user input may include various external inputs such as a portion of the user's body, light, heat, a pen, pressure, or the like. In FIG. 1, it is illustrated that the external input EIP is applied through the user's hand applied to the front surface FS when the external input EIP corresponds to a touch signal. However, the present disclosure is not limited thereto. For example, as described above, the external input EIP may be provided in various manners. the display device DD may detect the external input EIP applied to a side surface or a back surface of the display device DD depending on a structure of the display device DD, not limited to any one embodiment. In an embodiment, when the external input EIP corresponds to a proximity signal, the external input EIP may be applied through an ear or cheek that is a part of the user's body.

The power supply module PM supplies power necessary for overall operations of the display device DD. The power supply module PM may include a general battery module.

Each of the first electronic module EM1 and the second electronic module EM2 may include various functional modules for operating the display device DD.

The first electronic module EM1 may be directly mounted on a motherboard electrically connected to the display module 200 or may be mounted on a separate board so as to be electrically connected to the motherboard through a connector (not illustrated).

The first electronic module EM1 may include a control module CM, a wireless communication module TM, an image input module IIM, an audio input module AIM, a memory MM, and an external interface IF. Some of the modules are not mounted on the motherboard, but may be electrically connected to the motherboard through a flexible circuit board.

The control module CM controls overall operations of the display device DD. The control module CM may be a microprocessor. For example, the control module CM activates or deactivates the display module 200. The control module CM may control other modules such as a light emitting module LMM, the image input module IIM, the audio input module AIM, or the like based on a touch signal received from the display module 200.

The control module CM may be a microprocessor that is connected to the electronic module 500 so as to control an operation of the electronic module 500. In an embodiment, the control module CM may control overall operations of the electronic module 500. The control module CM may include a processor that controls the electronic module 500.

In an embodiment, the control module CM may be electrically connected to the display panel 210 and the input sensor 220 so as to control operations of the display panel 210 and the input sensor 220. The control module CM may control the display driver integrated circuit DC (see FIG. 2) that drives the display panel 210. The control module CM may control the sensor driving circuit TC (see FIG. 2) that drives the input sensor 220. The control module CM may provide the display driver integrated circuit DC and the sensor driving circuit TC with various signals according to a user input.

In an embodiment, the control module CM may control synchronization between the display panel 210 and the input sensor 220. For example, when a call mode is executed in response to a user input, the control module CM may deliver a command to the input sensor 220 such that the input sensor 220 is synchronized with the display panel 210.

The wireless communication module TM may transmit/receive wireless signals with another terminal by using Bluetooth or Wi-Fi. The wireless communication module TM may transmit/receive voice signals by using general communication lines. The wireless communication module TM may include a transmitter TM1 which modulates and transmits a transmission signal, and a receiver TM2 that demodulates a reception signal.

The image input module IIM converts an image signal into image data capable of being displayed on the display module 200. The audio input module AIM receives an external sound signal from a microphone in a recording mode and a speech recognition mode, or the like and converts the external sound signal into electrical voice data.

The external interface IF may operate as an interface that connects to an external charger, a wired/wireless data port, a card socket (e.g., a memory card, a SIM/UIM card, or the like), or the like.

The second electronic module EM2 may include an audio output module AOM, the light emitting module LMM, a light receiving module LRM, and the electronic module 500 according to an embodiment of the present disclosure. The second electronic module EM2 may be mounted directly on a motherboard, may be mounted on a separate board so as to be electrically connected to the display module 200 through a connector (not illustrated), or may be electrically connected to the first electronic module EM1.

The audio output module AOM converts the sound data received from the wireless communication module TM or audio data stored in the memory MM so as to be output to the outside.

The light emitting module LMM generates and outputs light. The light emitting module LMM may output infrared rays. The light emitting module LMM may include an LED element. The light receiving module LRM may detect infrared rays. When infrared rays having a predetermined level or more are detected, the light receiving module LRM may be activated. The light receiving module LRM may include a CMOS sensor. After infrared light being generated by the light emitting module LMM is output, the infrared light is reflected by an external object (e.g., a user's finger or face), and then the reflected infrared light may be incident on the light receiving module LRM. The electronic module 500 may capture an external image.

The electronic module 500 according to an embodiment of the present disclosure may be included in at least one of the first electronic module EM1 and the second electronic module EM2. For example, the second electronic module EM2 may include the electronic module 500 in addition to the audio output module AOM, the light emitting module LMM, and the light receiving module LRM. The electronic module 500 may detect an external subject by detecting an image received through the module area MA or may provide a sound signal such as voice, light such as infrared light, or the like to the outside through the module area MA. The electronic module 500 may include a camera module, an actuator, and the like so as to capture an external subject.

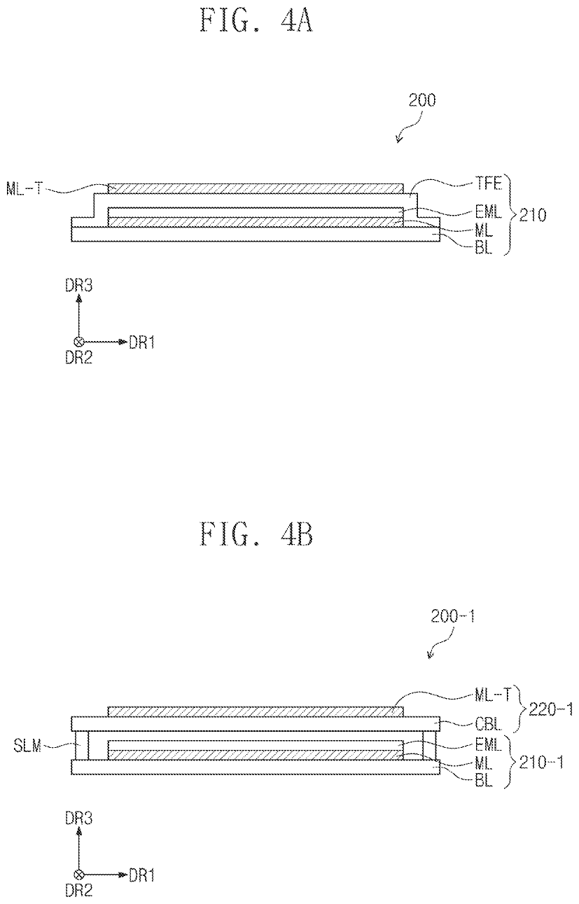

FIGS. 4A and 4B are cross-sectional views of a display module, according to an embodiment of the present disclosure.

FIG. 4A is a cross-sectional view of a display module according to an embodiment of the present disclosure. Referring to FIG. 4A, the display module 200 may include the display panel 210 and the input sensor 220. The display panel 210 may include a base layer BL, a circuit element layer ML, a light emitting element layer EML, and an encapsulation layer TFE. The input sensor 220 may include a sensing circuit layer ML-T.

According to an embodiment of the present disclosure, the display panel 210 and the input sensor 220 may be formed in continuous processes. That is, the sensing circuit layer ML-T may be directly formed on the encapsulation layer TFE. The input sensor 220 is directly disposed on the display panel 210 on the encapsulation layer TFE, and thus the input sensor 220 is affected by noise from the display driver integrated circuit DC when a screen of the display panel 210 is displayed. For example, when the input sensor 220 detects input signals, the input sensor 220 may be affected by the noise generated when the display panel 210 switches a screen.

The base layer BL may be a stacked structure including a silicon substrate, a plastic substrate, a glass substrate, an insulating film, or a plurality of insulating layers.

The circuit element layer ML may be disposed on the base layer BL. The circuit element layer ML may include a plurality of insulating layers, a plurality of conductive layers, and a semiconductor layer. The plurality of conductive layers of the circuit element layer ML may constitute signal wires or a control circuit of a pixel.

The light emitting element layer EML may be disposed on the circuit element layer ML. The light emitting element layer EML may include a light emitting layer that generates light. For example, a light emitting layer of the organic light emitting display panel may include an organic light emitting material. The light emitting layer of a quantum dot light emitting display panel may include at least one of a quantum dot and a quantum rod.

The sensing circuit layer ML-T may be disposed on the encapsulation layer TFE. The sensing circuit layer ML-T may include a plurality of insulating layers and a plurality of conductive layers. A plurality of conductive layers may constitute a sensing electrode for sensing an external input, a sensing wire connected to the sensing electrode, and a sensing pad connected to the sensing wire.

FIG. 4B is a cross-sectional view of a display module, according to an embodiment of the present disclosure. In the description of FIG. 4B, the same reference numerals are assigned to the same components described through FIG. 4A, and thus the descriptions thereof are omitted to avoid redundancy.

Referring to FIG. 4B, a display module 200-1 may include a display panel 210-1 and an input sensing unit 220-1. The display panel 210-1 may include the base layer BL, the circuit element layer ML, and the light emitting element layer EML. The input sensing unit 220-1 may include a cover substrate CBL and the sensing circuit layer ML-T.

The cover substrate CBL may be disposed on the light emitting element layer EML. The cover substrate CBL may be a stacked structure including a silicon substrate, a plastic substrate, a glass substrate, an insulating film, or a plurality of insulating layers. A predetermined space may be defined between the cover substrate CBL and the light emitting element layer EML. The space may be filled with air or inert gas. Furthermore, in an embodiment of the present disclosure, the space may be filled with a filler such as a silicone-based polymer, an epoxy-based resin, an acrylic resin, or the like.

A coupling member SLM may be disposed between the base layer BL and the cover substrate CBL. The coupling member SLM may couple the base layer BL and the cover substrate CBL. The coupling member SLM may include an organic material such as a photocurable resin or a photoplastic resin, or may include an inorganic material such as a frit seal, and is not limited to any one embodiment.

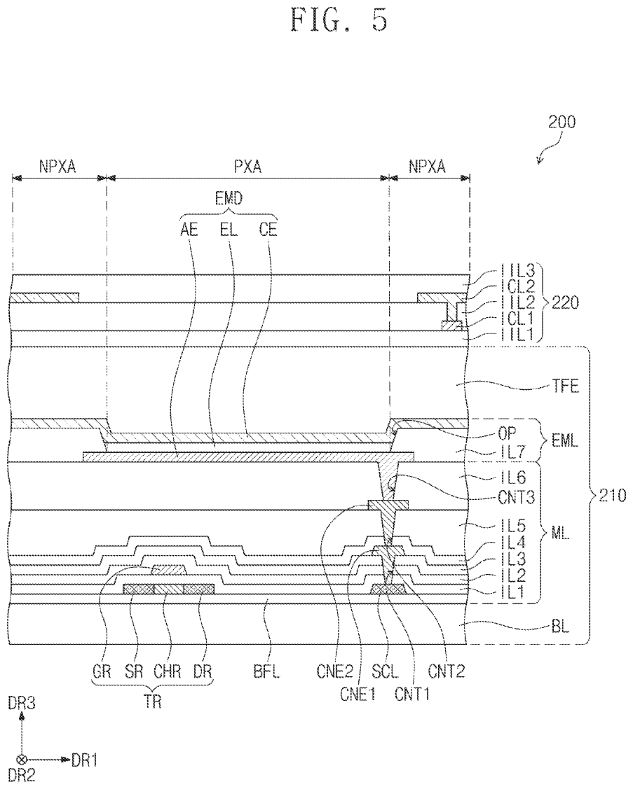

FIG. 5 is an enlarged cross-sectional view of a display module according to an embodiment of the present disclosure.

Referring to FIG. 5, the display module 200 may include the display panel 210 and the input sensor 220 directly disposed on the display panel 210. The display panel 210 may include the base layer BL, the circuit element layer ML, the light emitting element layer EML, and the encapsulation layer TFE.

The base layer BL may provide a base surface on which the circuit element layer ML is disposed. The base layer BL may be a glass substrate, a metal substrate, a polymer substrate, or the like. However, an embodiment is not limited thereto, and the base layer BL may be an inorganic layer, an organic layer, or a composite material layer.

The base layer BL may have a multi-layer structure. For example, the base layer BL may have a three-layer structure including a synthetic resin layer, an adhesive layer, and a synthetic resin layer. In particular, the synthetic resin layer may include polyimide-based resin. In addition, the synthetic resin layer may include at least one of acrylate-based resin, methacrylate-based resin, polyisoprene-based resin, vinyl-based resin, epoxy-based resin, urethane-based resin, cellulose-based resin, siloxane-based resin, polyamide-based resin, and perylene-based resin.

The circuit element layer ML may be disposed on the base layer BL. The circuit element layer ML may include an insulating layer, a semiconductor pattern, a conductive pattern, a signal line, and the like. The insulating layer, the semiconductor layer, and the conductive layer may be formed on the base layer BL in a manner such as coating, evaporation, or the like. Afterward, the insulating layer, the semiconductor layer, and the conductive layer may be selectively patterned by performing a photolithography process a plurality of times. Afterward, the semiconductor pattern, the conductive pattern, and the signal line included in the circuit element layer ML may be formed.

At least one inorganic layer is formed on an upper surface of the base layer BL. The inorganic layer may include at least one of aluminum oxide, titanium oxide, silicon oxide, silicon oxynitride, zirconium oxide, and hafnium oxide. The inorganic layer may be formed of a plurality of layers. The inorganic layers, each of which has a plurality of layers, may constitute a barrier layer and/or a buffer layer. In an embodiment, it is illustrated that the display panel 210 includes a buffer layer BFL.

The buffer layer BFL may improve the bonding force between the base layer BL and a semiconductor pattern. The buffer layer BFL may include a silicon oxide layer and a silicon nitride layer. The silicon oxide layer and the silicon nitride layer may be stacked alternately.

The semiconductor pattern may be disposed on the buffer layer BFL. The semiconductor pattern may include polysilicon. However, the present disclosure is not limited thereto, and the semiconductor pattern may include amorphous silicon or metal oxide.

FIG. 5 only illustrates a part of the semiconductor pattern, and the semiconductor pattern may be further disposed in another area. The semiconductor pattern may be arranged to have a predetermined configuration throughout pixels. The semiconductor pattern may alter electrical characteristics depending on dopant concentration. The semiconductor pattern may include a doping area and a non-doping area. The doping area may be doped with an N-type dopant or a P-type dopant. A PMOS transistor may include a doping area doped with the P-type dopant. An NMOS transistor may include a doping area doped with the N-type dopant.

The doping area has higher conductivity than the non-doping area and may substantially operate as an electrode or signal line. The non-doping area may substantially correspond to an active area (or a channel area) of a transistor. In other words, a part of the semiconductor pattern may be the active area of the transistor and the other part may be a source area or a drain area of the transistor.

Each of the pixels may include seven transistors, one capacitor, and a light emitting element. The equivalent circuit of a pixel may be modified in various shapes. A single transistor TR and a light emitting element EMD included in a pixel are illustrated in FIG. 5.

A source area SR, an active area CHR, and a drain area DR of the transistor TR may be formed of the semiconductor pattern. The source area SR and the drain area DR may be provided in opposite sides of the active area CHR in a plan view. FIG. 5 illustrates a part of a signal line SCL disposed on the same layer as the semiconductor pattern. Although not separately illustrated in FIG. 5, the signal line SCL may be electrically connected to the drain area FR of the transistor TR in a plan view.

A first insulating layer IL1 may be disposed on the buffer layer BFL. The first insulating layer IL1 may overlap a plurality of pixels in common and may cover the semiconductor pattern. The first insulating layer IL1 may be an inorganic layer and/or an organic layer, and may have a single-layer structure or a multi-layer structure. The first insulating layer IL1 may include at least one of aluminum oxide, titanium oxide, silicon oxide, silicon oxynitride, zirconium oxide, and hafnium oxide. In an embodiment, the first insulating layer IL1 may be a single layer of silicon oxide. Not only the first insulating layer IL1 but also an insulating layer of the circuit element layer ML to be described later may be an inorganic layer and/or an organic layer, and may have a single-layer structure or a multi-layer structure. The inorganic layer may include at least one of the above-described materials, but is not limited thereto.

A gate GR of the transistor TR is disposed on the first insulating layer ILL The gate GR may be a part of a metal pattern. The gate GR overlaps the active area CHR in a plan view. In a process of doping the semiconductor pattern, the gate GR may function as a self-aligned mask.

A second insulating layer IL2 is disposed on the first insulating layer IL1 and may cover the gate GR. The second insulating layer IL2 may overlap pixels in common. The second insulating layer IL2 may be an inorganic layer and/or an organic layer, and may have a single-layer structure or a multi-layer structure. In an embodiment, the second insulating layer IL2 may be a single layer of silicon oxide.

A third insulating layer IL3 may be disposed on the second insulating layer IL2. In an embodiment, the third insulating layer IL3 may be a single layer of silicon oxide.

A first connection electrode CNE1 may be disposed on the third insulating layer IL3. The first connection electrode CNE1 may be connected to the signal line SCL through a contact hole CNT1 formed in the first, second, and third insulating layers ILL IL2, and IL3.

A fourth insulating layer IL4 may be disposed on the third insulating layer IL3. The fourth insulating layer IL4 may be a single layer of silicon oxide. A fifth insulating layer IL5 may be disposed on the fourth insulating layer IL4. The fifth insulating layer IL5 may be an organic layer.

A second connection electrode CNE2 may be disposed on the fifth insulating layer IL5. The second connection electrode CNE2 may be connected to the first connection electrode CNE1 through a contact hole CNT2 formed in the fourth insulating layer IL4 and the fifth insulating layer IL5.

A sixth insulating layer IL6 may be disposed on the fifth insulating layer IL5 so as to cover the second connection electrode CNE2. The sixth insulating layer IL6 may be an organic layer. The light emitting element layer EML may be disposed on the circuit element layer ML. The light emitting element layer EML may include the light emitting element EMD. For example, the light emitting element layer EML may include an organic light emitting material, a quantum dot, a quantum rod, a micro-LED, or a nano-LED. The light emitting element EMD may include a first electrode AE, a light emitting layer EL, and a second electrode CE.

The first electrode AE may be disposed on the sixth insulating layer IL6. The first electrode AE may be connected to the second connection electrode CNE2 through a contact hole CNT3 formed in the sixth insulating layer IL6.

A pixel defining film IL7 may be disposed on the sixth insulating layer IL6 so as to cover a part of the first electrode AE. An opening OP is defined in the pixel defining film IL7. The opening OP of the pixel defining film IL7 exposes at least part of the first electrode AE. In an embodiment, a light emitting area PXA is defined to correspond to a partial area of the first electrode AE exposed by the opening OP. A non-light emitting area NPXA may surround the light emitting area PXA.

The light emitting layer EL may be disposed on the first electrode AE. The light emitting layer EL may be disposed in the opening OP. That is, the light emitting layer EL may be separately formed on each of pixels. When the light emitting layer EL is separately formed on each of the pixels, each of the light emitting layers EL may emit light of at least one color of blue, red, and green. However, the present disclosure is not limited thereto, and the light emitting layer EL may be connected and provided to each of the pixels in common. In this case, the light emitting layer EL may provide blue light or white light.

The second electrode CE may be disposed on the light emitting layer EL. The second electrode CE may be integrally disposed in a plurality of pixels in common. A common voltage may be provided to the second electrode CE, and the second electrode CE may be referred to as a common electrode.

Although not illustrated in FIG. 5, a hole control layer may be interposed between the first electrode AE and the light emitting layer EL. The hole control layer may be disposed in the light emitting area PXA and the non-light emitting area NPXA in common. The hole control layer may include a hole transport layer and may further include a hole injection layer. An electron control layer may be interposed between the light emitting layer EL and the second electrode CE. The electron control layer may include an electron transport layer, and may further include an electron injection layer. The hole control layer and the electron control layer may be formed in common in a plurality of pixels, using an open mask. The encapsulation layer TFE may be disposed on the light emitting element layer EML. The encapsulation layer TFE may include an inorganic layer, an organic layer, and an inorganic layer which are sequentially stacked, but layers constituting the encapsulation layer TFE are not limited thereto.

The inorganic layers may protect the light emitting element layer EML from moisture and oxygen. The organic layer may protect the light emitting element layer EML from foreign objects such as dust particles. The inorganic layers may include a silicon nitride layer, a silicon oxynitride layer, a silicon oxide layer, a titanium oxide layer, an aluminum oxide layer, or the like. The organic layer may include an acrylate-based organic layer, but is not limited thereto.

The input sensor 220 may be directly formed on the display panel 210 through continuous processes. The input sensor 220 may include a base layer IIL1, a first conductive layer ICL1, a detection insulating layer IIL2, a second conductive layer ICL2, and a cover insulating layer IIL3.

The base layer IIL1 may be an inorganic layer including one of silicon nitride, silicon oxynitride, and silicon oxide. Alternatively, the base layer IIL1 may be an organic layer including an epoxy resin, an acrylate resin, or an imide-based resin. The base layer IIL1 may have a single-layer structure or may have a multi-layer structure stacked in the third direction DR3.

Each of the first conductive layer ICL1 and the second conductive layer ICL2 may have a single-layer structure or may have a multi-layer structure stacked in the third direction DR3. A conductive layer of a single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), indium zinc tin oxide (IZTO), or the like. Besides, the transparent conductive layer may include a conductive polymer such as PEDOT, a metal nano wire, graphene, and the like.

A conductive layer of the multi-layer structure may include metal layers. For example, the metal layers may have a three-layer structure of titanium/aluminum/titanium. The conductive layer of the multi-layer structure may include at least one metal layer and at least one transparent conductive layer.

At least one of the detection insulating layer IIL2 and the cover insulating layer IIL3 may include an inorganic film. The inorganic film may include at least one of aluminum oxide, titanium oxide, silicon oxide, silicon oxynitride, zirconium oxide, and hafnium oxide.

At least one of the detection insulating layer IIL2 and the cover insulating layer IIL3 may include an organic film. The organic film may include at least one of acrylate-based resin, methacrylate-based resin, polyisoprene-based resin, vinyl-based resin, epoxy-based resin, urethane-based resin, cellulose-based resin, siloxane-based resin, polyimide-based resin, polyamide-based resin, and perylene-based resin.

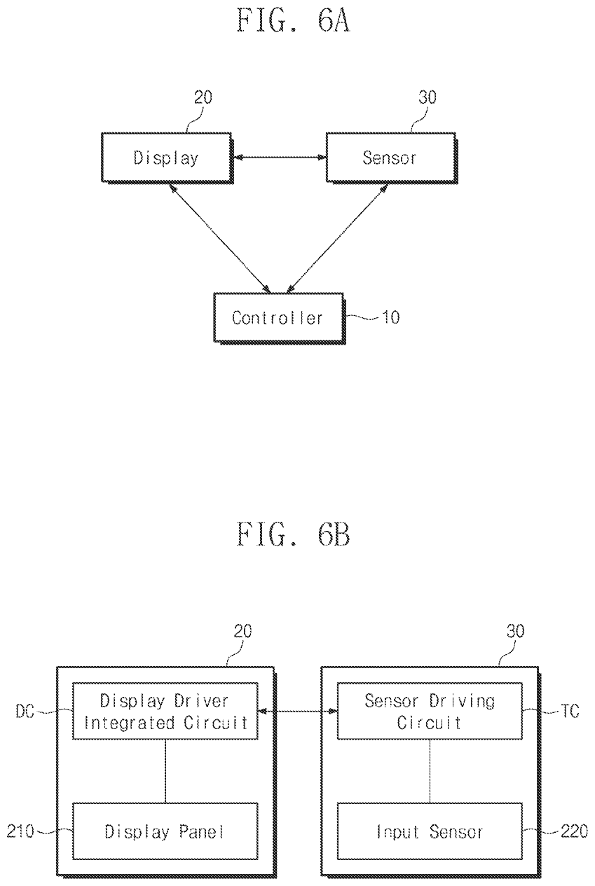

FIGS. 6A and 6B are block diagrams of a display device according to an embodiment of the present disclosure.

Referring to FIG. 6A, a display device includes a controller 10, a display 20, and a sensor 30.

The controller 10 may control the signal transmission between the display 20 and the sensor 30 and operations of the display 20 and the sensor 30. The controller 10 may include a control module CM (FIG. 3). The controller 10 may deliver corresponding commands to the display 20 and the sensor 30 in response to a user input received through an input sensor.

In an embodiment, when a user touches a call button CAL (see FIG. 1), the controller 10 may execute a call mode. When the call mode is executed, the controller 10 may execute a proximity sensing mode. The proximity sensing mode may correspond to a mode in which the input sensor 220 senses a proximity signal instead of a touch signal. Herein, the touch signal may correspond to a signal applied to the display device DD at a point in time when a part (e.g., a finger) of the user's body directly touches the display surface FS (see FIG. 1) of the display device DD (see FIG. 1). The proximity signal may correspond to a signal applied to the display device at a point in time when a part (e.g., an ear) of the user's body is close to the display surface FS.

Referring to FIGS. 6A and 6B, the display 20 includes the display panel 210 and the display driver integrated circuit DC.

When the proximity sensing mode is activated in the display 20, the display driver integrated circuit DC may reduce the luminance of the display panel 210 less than or equal to target luminance. Herein, the target luminance corresponds to optimal luminance of the display panel 210 that is required by the input sensor 220 to sense the proximity signal in the proximity sensing mode. The proximity signal may have the strength of a signal smaller than the touch signal. Accordingly, the proximity signal is vulnerable to noise of the display panel 210. The display driver integrated circuit DC according to an embodiment of the present disclosure may reduce the luminance of the display panel 210 less than the target luminance in the proximity sensing mode, thereby reducing noise generated from the display panel 210.

The sensor 30 may include the input sensor 220 and the sensor driving circuit TC. The input sensor 220 is disposed on the display panel 210. The input sensor 220 may overlap the display panel 210 in a thickness direction of the display panel 210. The sensor driving circuit TC drives the input sensor 220. The sensor driving circuit TC may be integrated with the display driver integrated circuit DC or may be implemented separately from the display driver integrated circuit DC as shown in FIG. 6B. The sensor driving circuit TC may be disposed on the main circuit board MB (see FIG. 2).

In the proximity sensing mode, the sensor 30 may operate in synchronization with the display 20. In other words, when the display panel 210 has less than the target luminance, the sensor 30 may sense the proximity signal through the input sensor 220.

In more detail, the sensor driving circuit TC may be synchronized with the display driver integrated circuit DC in the proximity sensing mode. The sensor driving circuit TC may receive luminance information of the display panel 210 from the display driver integrated circuit DC. When the luminance of the display panel 210 has less than the target luminance, the sensor driving circuit TC may sense the proximity signal through the input sensor 220.

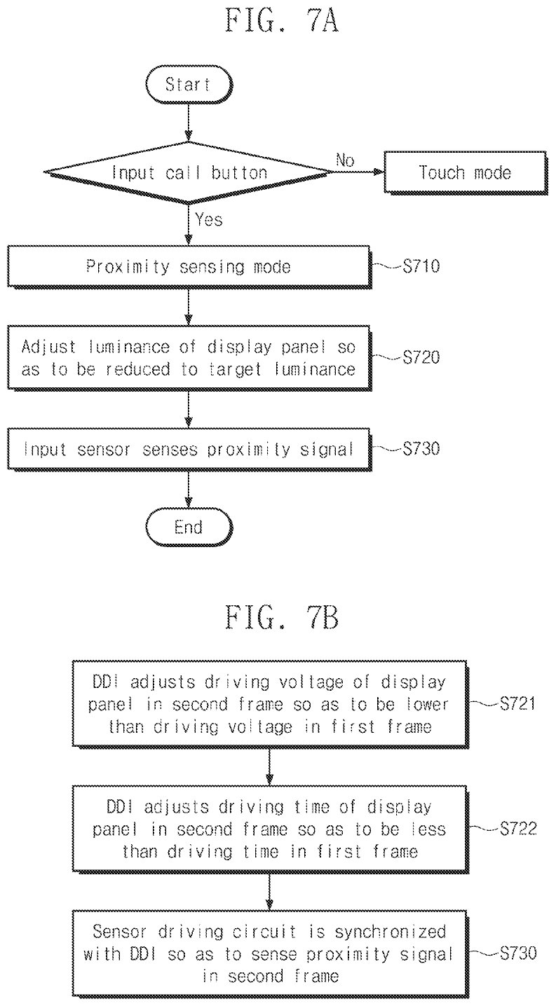

FIGS. 7A and 7B are flowcharts illustrating a proximity signal sensing method using an input sensor according to an embodiment of the present disclosure.

FIG. 7A is a flowchart schematically illustrating a proximity signal sensing method using an input sensor.

In FIG. 7A, a proximity signal sensing method using an input sensor may be initiated by executing a proximity sensing mode when a user presses a call button (operation S710).

When the user does not press the call button, a display device does not operate in the proximity sensing mode, but operates in a normal touch mode.

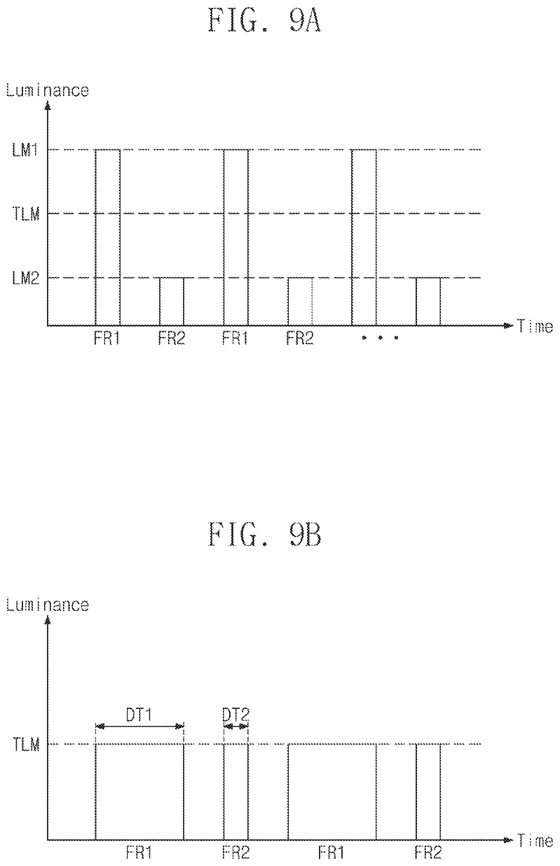

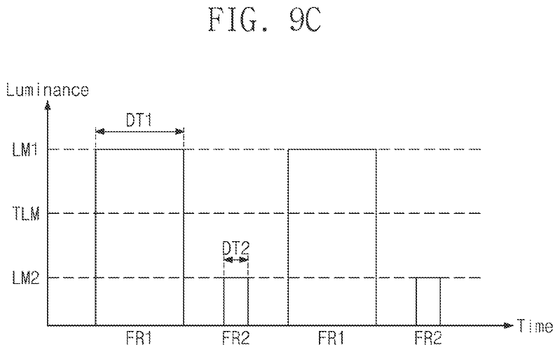

When the proximity sensing mode is activated, the display driver integrated circuit DC may adjust the luminance of a display panel to be less than the target luminance (operation S720). The adjusting method of the display driver integrated circuit DC will be described in detail with reference to FIGS. 7B and 9A to 9C.

When the display panel is driven at less than the target luminance, the sensor driving circuit allows the input sensor to sense a proximity signal (operation S730). In an embodiment, the display panel is driven at less than the target luminance to reduce noise generation, thereby improving the proximity signal sensing performance of the input sensor due to the reduced noise of the display panel.

FIG. 7B is a flowchart illustrating a proximity signal sensing method using an input sensor according to an embodiment of the present disclosure. FIG. 7B illustrates a method of reducing luminance of a display panel to target luminance.

In FIG. 7B, a DDI may adjust a driving voltage of the display panel in a second frame so as to be lower than a driving voltage of the display panel in a first frame (operation S721). That is, the DDI may differently apply driving voltages for each of frames that alternate with each other while the display panel is driven. The target luminance may correspond to luminance at an average driving voltage obtained by averaging the driving voltage in the first frame and the driving voltage in the second frame.

In an embodiment, the DDI may adjust the driving time of the display panel in the second frame so as to be less than the driving time of the display panel in the first frame (operation S722). In other words, the DDI may differently set driving times for each of frames that alternate with each other. The target luminance may correspond to luminance of the display panel in an average driving time obtained by averaging the driving time in the first frame and the driving time in the second frame.

In an embodiment, one of operation S721 and operation S722 may be omitted.

A sensor driving circuit synchronized with the display driver integrated circuit DC may sense a proximity signal after the display driver integrated circuit DC adjusted the luminance of the display panel to have luminance less than the target luminance. The sensor driving circuit senses the proximity signal only in the second frame having low driving voltage and/or little driving time. That is, the sensor driving circuit may detect the proximity signal only in the frame having low luminance of the display panel. Because the noise applied from the display panel to the input sensor is little at low luminance, the input sensor may effectively sense the proximity signal. In this regard, it will be further described with reference to FIGS. 9A to 9C.

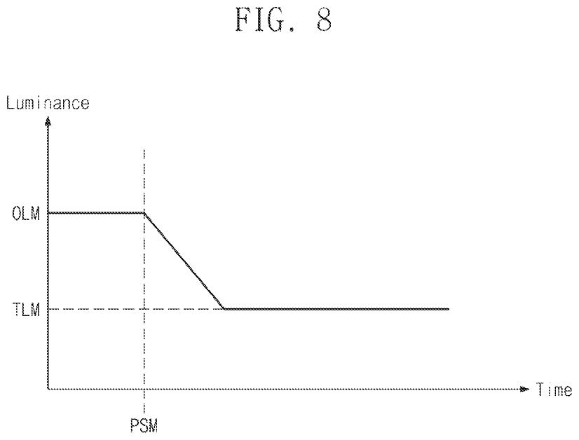

FIG. 8 is a graph illustrating a decrease in luminance of a display panel, according to an embodiment of the present disclosure.

In FIG. 8, when a proximity sensing mode PSM is executed, a display driver integrated circuit DC may gradually reduce luminance from current luminance OLM of a display panel to target luminance TLM. When the luminance reaches the target luminance TLM in the proximity sensing mode PSM, the display driver integrated circuit DC may uniformly maintain the luminance.

FIGS. 9A to 9C are graphs illustrating a method of lowering luminance of a display panel according to an embodiment of the present disclosure.

FIG. 9A illustrates a method of lowering luminance by adjusting a driving voltage of a display panel. FIG. 9B illustrates a method of lowering luminance by adjusting a driving time of a display panel. FIG. 9C illustrates a method of lowering luminance by adjusting a driving voltage and driving time of a display panel.

Referring to FIGS. 9A to 9C, a display may include a first frame FR1 and a second frame FR2. The first frame FR1 and the second frame FR2 alternate with each other. The second frame FR2 follows the first frame FR1.

In FIG. 9A, a display driver integrated circuit DC may operate in a state where the second luminance LM2 of the display panel in the second frame FR2 is set to be lower than the first luminance LM1 of the display panel in the first frame FR1. The target luminance TLM may correspond to luminance obtained by averaging the first luminance LM1 and the second luminance LM2. That is, the DDI may determine the target luminance TLM through an average driving voltage by setting the driving voltage in the first frame FR1 to be high and setting the driving voltage in the second frame FR2 to be low.

A sensor driving circuit may detect a proximity signal during the second frame FR2 after adjusting luminance of the second frame FR2. The second luminance LM2 in the second frame FR2 is lower than the target luminance TLM. The target luminance TLM may be determined as luminance having a level at which the user is capable of perceiving a screen. The second luminance LM2 is determined as low luminance to reduce noise of the display panel. According to an embodiment of the present disclosure, the display driver integrated circuit DC may set the second luminance LM2 to have a luminance less than the target luminance which is adequate for sensing the proximity signal. Accordingly, the performance of detecting the proximity signal may be improved while the user is capable of perceiving a screen during a call.

In FIG. 9B, the display driver integrated circuit DC may adjust the luminance of the display panel by setting a second driving time DT2 of the second frame FR2 to be less than a first driving time DT1 in the first frame FR1. The luminance during the second driving time DT2 is lower than the luminance during the first driving time DT1.

In an embodiment, the driving voltage in the first frame FR1 is the same as the driving voltage in the second frame FR2. An average driving time is a value obtained by averaging the first driving time DT1 and the second driving time DT2. The target luminance TLM may be determined depending on the average driving time.

The sensor driving circuit, which is synchronized with the display driver integrated circuit DC, may drive an input sensor so as to sense the proximity signal during the second frame FR2 after adjusting luminance by altering the second driving time DT2.

In FIG. 9C, the display driver integrated circuit DC may adjust the luminance of the display panel so as to be reduced to the target luminance by adjusting both the driving voltage and driving time.

The display driver integrated circuit DC may decrease the driving voltage and driving time in the second frame FR2. Accordingly, the DDI may drive a display panel at less than the target luminance TLM.

The sensor driving circuit may detect a proximity signal during the second frame after adjusting the driving voltage and the driving time of the second frame FR2. The luminance of the display panel in the second frame FR2 is lower than the luminance of the display panel in the first frame FR1. Accordingly, the noise of the display panel is little, and thus the proximity signal may be effectively sensed.

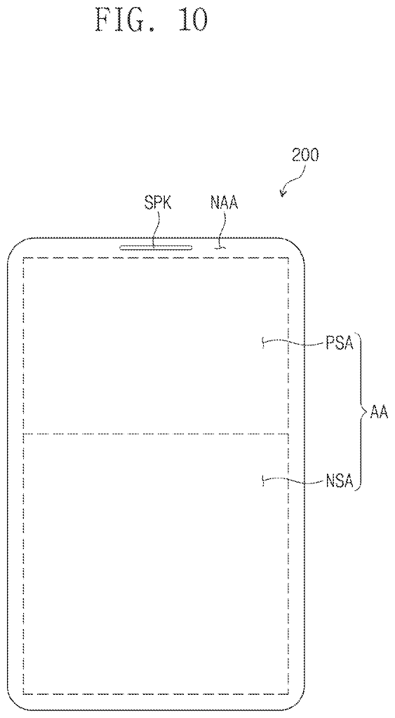

FIG. 10 is a plan view of a display module according to an embodiment of the present disclosure.

In an embodiment, a first area PSA and a second area NSA may be defined in the display panel 210 of the display device DD. The first area PSA and the second area NSA may be defined in an active area AA. The first area PSA and the second area NSA are defined to be adjacent to each other. In an embodiment, the first area PSA may be disposed adjacent to a speaker module SPK. In other words, the first area PSA may be located closer to a user's ear than the second area NSA while the user is on a call.

In an embodiment, a display driver integrated circuit DC may lower luminance in the first area PSA of a display panel to target luminance in a proximity sensing mode. In other words, the display driver integrated circuit DC may only adjust the luminance in the first area PSA, which is close to the user's ear, while maintaining the luminance in the second area NSA as it is.

A sensor driving circuit may sense a proximity signal entered into the first area PSA. That is, the sensor driving circuit may reduce the influence of noise on the display panel by sensing the proximity signal in the first area PSA in which the display panel operates at the target luminance.

Referring to FIGS. 9A to 9C, the display driver integrated circuit DC may adjust the driving voltage and/or driving time for a second frame following a first frame so that the luminance of the display panel to be less than the target luminance in the first area PSA. That is, when the display driver integrated circuit DC drives pixels in the first area PSA of the display panel, the display driver integrated circuit DC may adjust the driving voltage and/or driving time of the second frame FR2 to be less than the target luminance.

In the first area PSA, the display driver integrated circuit DC may reduce the luminance of the second frame FR2 less than the luminance of the first frame FR1. The sensor driving circuit may sense the proximity signal in the second frame FR2. That is, the display device according to an embodiment may adjust the luminance of the second frame FR2 of the display panel only in the first area PSA and may detect the proximity signal, which is sensed through an input sensor in the second frame FR2 having low luminance. The redundant descriptions are given with reference to FIGS. FIGS. 9A to 9C.

As described above, embodiments are disclosed in drawings and specifications. Specific terms are used herein, but are only used for the purpose of describing the present disclosure, and are not used to limit the meaning or the scope of the present disclosure described in claims. Therefore, it will be understood that various modifications and other equivalent embodiments are possible from this point by those skilled in the art. The technical protection scope of the present disclosure will be defined by the technical spirit of the appended claims.

According to an embodiment of the present disclosure, a display device and a proximity signal sensing method using an input sensor may reduce noise caused by a display panel in a process of sensing a proximity signal through an input sensor.

According to an embodiment of the present disclosure, a display device and a proximity signal sensing method using an input sensor may reduce noise caused by a display panel by reducing luminance of the display panel while the input sensor senses a proximity signal, thereby improving a proximity signal sensing performance.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a controller configured to execute a proximity sensing mode in which a proximity signal is sensed in response to a start signal;
a display configured to reduce luminance of a display panel to target luminance when the proximity sensing mode is executed; and
a sensor configured to sense the proximity signal after reducing the luminance of a display panel to the target luminance.

2. The display device of claim 1, wherein the start signal is a signal for starting a phone call by a user.

3. The display device of claim 1, wherein the display includes the display panel and a display driver integrated circuit electrically connected to the display panel, and
wherein the display driver integrated circuit reduces the luminance of the display panel to the target luminance.

4. The display device of claim 3, wherein the display includes a first frame and a second frame that follows the first frame, and
wherein first luminance of the display panel in the first frame is greater than second luminance of the display panel in the second frame.

5. The display device of claim 4, wherein a driving voltage applied from the display driver integrated circuit to the display panel in the second frame is less than a driving voltage applied in the first frame.

6. The display device of claim 5, wherein the sensor senses the proximity signal in the second frame.

7. The display device of claim 4, wherein a second driving time in the second frame is less than a first driving time in the first frame.

8. The display device of claim 6, wherein the sensor senses the proximity signal in the second frame.

9. The display device of claim 4, wherein a driving voltage of the second frame is less than a driving voltage of the first frame, and a driving time in the second frame is less than a driving time in the first frame.

10. The display device of claim 7, wherein the sensor senses the proximity signal in the second frame.

11. The display device of claim 4, wherein the target luminance is an average of the first luminance and the second luminance.

12. The display device of claim 1, wherein the sensor includes an input sensor and a sensor driving circuit electrically connected to the input sensor, and
wherein the sensor driving circuit is synchronized with the display so as to detect the proximity signal at the target luminance.

13. The display device of claim 1, wherein, when the proximity sensing mode is executed, the display gradually reduces the luminance to the target luminance.

14. The display device of claim 1, wherein the display device include a first area disposed adjacent to a speaker and a second area disposed adjacent to the first area, and
wherein the display reduces the luminance of the display panel in the first area to the target luminance.

15. The display device of claim 14, wherein the sensor senses the proximity signal in the first area.

16. The display device of claim 1, wherein the sensor is disposed on the display so as to overlap the display in a plan view.

17. A proximity signal sensing method using an input sensor, the method comprising:
executing a proximity sensing mode in which the input sensor senses a proximity signal instead of a touch signal when a controller receives a start signal;
reducing luminance of a display panel to target luminance when the proximity sensing mode is executed; and
sensing the proximity signal by a sensor synchronized with the display.

18. The method of claim 17, wherein the display panel includes a first frame and a second frame that follows the first frame, and
wherein first luminance of the display panel in the first frame is greater than second luminance of the display panel in the second frame.

19. The method of claim 18, wherein the display includes a display driver integrated circuit, and
wherein the display driver integrated circuit sets a driving voltage of the second frame so as to be lower than a driving voltage of the first frame.

20. The method of claim 19, wherein the sensor includes a sensor driving circuit, and
wherein the sensor driving circuit detects the proximity signal in the second frame.
